(19) United States
(12) Patent Application Publication
(10) Pub. No.: US 2026/0018229 A1
(43) Pub. Date: Jan. 15, 2026

(54) CONTROLLER, MEMORY MODULE AND MEMORY SYSTEM

(71) Applicant: SK hynix Inc., Icheon-si (KR)

(72) Inventor: Hyeong Ju NA, Icheon-si (KR)

(21) Appl. No.: 18/955,528

(22) Filed: Nov. 21, 2024

(30) Foreign Application Priority Data
Jul. 10, 2024 (KR) 10-2024-0090947

(51) Int. Cl. G11C 29/42; G11C 29/18; G11C 29/46

(52) U.S. Cl. CPC G11C 29/42; G11C 29/18; G11C 29/46; G11C 2029/1802

(57) ABSTRACT

According to the present disclosure, if a defective area is detected among a plurality of unit storage areas of memory included in a memory system, the corresponding area may be set as an unuse area, and the remaining area may be configured as a second group storage area different from the existing first group storage area, and the ratio of parity data or the type of data to be stored may be configured to be different from each other, thereby minimizing the reduction or the degradation of the available unit storage area due to the occurrence of an unuse area and improving the usage efficiency of the memory system.

### CROSS-REFERENCE TO RELATED APPLICATION

The present application claims priority under 35 U.S.C. § 119 (a) to Korean patent application number 10-2024-0090947 filed in the Korean Intellectual Property Office on Jul. 10, 2024, which is incorporated herein by reference in its entirety.

### TECHNICAL FIELD

Embodiments of the present disclosure relate to a controller, a memory module and a memory system.

### BACKGROUND

A memory system may include at least one memory for storing data. The memory system may include a memory controller that controls operations of at least one memory. The memory controller may control an operation of writing data to the memory or reading data written to the memory.

A memory system may include a plurality of memories, and may include a memory package in which a plurality of memories are packaged. A plurality of memory packages may be included in the memory system.

Data may be stored and managed by using the storage areas of each of the plurality of memories included in the memory system, and there may occur a failure of the storage areas of some of the memories. The storage areas associated with the defective storage areas may not all be available, which may cause a problem in that the available capacity of the memory system may be reduced.

### SUMMARY

Embodiments of the disclosure may provide a configuration capable of maximizing the use of the remaining storage area of the memory when a failure occurs in a part of the storage area of the memory included in a memory system.

Embodiments of the disclosure may provide a memory system including an N (where N is an integer greater than or equal to 2) number of memory devices each including a plurality of unit storage areas, and a controller configured to set at least one use area and at least one unuse area from among the plurality of unit storage areas in the N memory devices, to control a first data processing for a first group storage area including a first use area included in each of the N memory devices, and to control a second data processing for a second group storage area, which excludes at least one of the N memory devices including an unuse area after the unuse area is determined, wherein the second group storage area includes a second use area included in each of the remaining memory devices from among the N memory devices.

Embodiments of the disclosure may provide a controller including an address decoder for checking a memory address corresponding to a host address according to a command received from a host device, and a control circuit configured to set a plurality of unit storage areas included in an N (where N is an integer greater than or equal to 2) number of memory devices as a use area or an unuse area, and control a first data processing for a first group storage area including a first use area included in each of the N memory devices or a second data processing for a second group storage area including a second use area included in each of the memory devices remaining after excluding at least one memory device with an unuse area from among the N memory devices.

Embodiments of the disclosure may provide a memory module including a first memory including a plurality of first unit storage areas with at least one first use area and at least one second use area, a second memory including a plurality of second unit storage areas with at least one first use area and at least one second use area, a third memory including a plurality of third unit storage areas with at least one first use area and at least one unuse area, and a memory controller configured to control an operation for a first group storage area including the first use area of the first memory, the first use area of the second memory, and the first use area of the third memory, or control an operation for a second group storage area including the second use area of the first memory and the second use area of the second memory.

According to embodiments of the present disclosure, even if a failure occurs in some storage areas of a memory included in a memory system, the remaining storage area may be utilized to the maximum extent possible, thereby preventing a degradation of the performance of the memory system due to the occurrence of a defective storage area and efficiently utilizing the storage capacity of the memory included in the memory system.

### BRIEF DESCRIPTION OF THE DRAWINGS

FIG. 1 illustrates a schematic configuration of a memory system according to embodiments of the present disclosure.

FIG. 2 illustrates a configuration of a memory device according to embodiments of the present disclosure.

FIG. 3 illustrates a configuration of a controller according to embodiments of the present disclosure.

FIG. 4 illustrates a method for reducing available capacity of a memory system according to embodiments of the present disclosure.

FIG. 5 illustrates a method of processing a command of a memory system when available data storage capacity is reduced according to embodiments of the present disclosure.

FIGS. 6 to 9 illustrate examples of methods of operating a memory system depending on whether available capacity is reduced according to embodiments of the present disclosure.

FIG. 10 illustrates a method of operating a memory module depending on whether a faulty chip is included according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings. Further, in the following description of examples or embodiments of the present disclosure, detailed descriptions of well-known functions and components incorporated herein will be omitted when it is determined that the description may make the subject matter in some embodiments of the present disclosure more unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, or manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance range or error margin that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

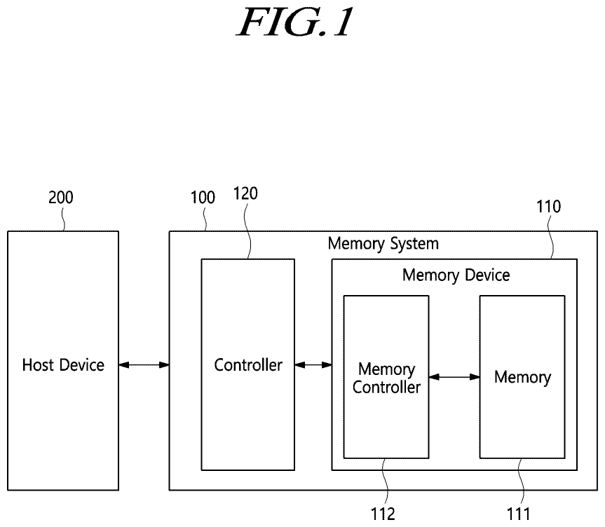

FIG. 1 illustrates a schematic configuration of a memory system according to embodiments of the present disclosure.

Referring to FIG. 1, a memory system 100 may include at least one memory device 110. The memory system 100 may include a controller 120 for controlling the operation of the memory device 110. The controller 120 may control the operation of the memory device 110 based on a command received from an external device or an internal command.

The memory device 110 may include at least one memory 111 storing data.

The memory 111 may be, for example, a volatile memory such as DRAM, SDRAM, DDR SDRAM, and LPDDR SDRAM, but the memory 111 according to embodiments of the present disclosure is not limited thereto. The memory 111 may also be a non-volatile memory such as a NAND flash memory, a 3D NAND flash memory, or a NOR flash memory. In addition, some of the memory 111 included in the memory system 100 may be volatile memory, and some may be non-volatile memory.

In addition, the memory 111 may be one of various types of memory, such as a resistive memory (e.g., ReRAM), a phase-change memory, a magnetoresistive memory, a ferroelectric memory, or a spin transfer torque-magnetic memory (e.g., SST-MRAM). In addition, the memory 111 may be a processing-in-memory having an operation function or a data processing function, depending on the application.

The memory device 110 may include a memory controller 112 that directly controls the operation of the memory 111.

A memory controller 112 may control, for example, an operation of writing data to the memory 111 or reading data written to the memory 111. Memory controllers 112 may be included in the memory device 110 to correspond to each memory 111 included in the memory device 110, or a memory controller 112 may be included in the memory device 110 to correspond to two or more memories 111.

The memory controller 112 may be disposed in the memory device 110 separately from the controller 120, which is included in the memory system 100. In some cases, at least some of the functions of the memory controller 112 may be implemented by being integrated with the controller 120. The memory controller 112 may control the operation of the memory 111 based on commands and data received from the controller 120.

The controller 120 may communicate with a device located outside the memory system 100, and control the operation of the memory device 110. The memory system 100 may be, for example, a device that communicates with an external device and operates based on a compute express link (CXL) standard, and the controller 120 may communicate with an external device and control the memory device 110 according to the CXL standard. In this case, the controller 120 may be distinguished from the memory controller 112 of the memory device 110, and may be referred to as a CXL controller.

The controller 120 may control the operation of the memory device 110 based on a command and data received from a host device 200 located outside the memory system 100.

The host device 200 may be a computer, an ultra-mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a computer network, one of various electronic devices configuring a telematics network, an RFID (radio frequency identification) device, and a mobility device (e.g., a vehicle, a robot or a drone) capable of driving under human control or autonomous driving, as non-limiting examples. Alternatively, the host device 200 may be a virtual reality (VR) device providing 2D or 3D virtual reality images or an augmented reality (AR) device providing augmented reality images. In addition to the examples described above, the host device 200 may be any one of various electronic devices that require a memory system 100 capable of storing data for data processing.

The host device 200 may include at least one operating system (OS). The operating system may generally manage and control the function and operation of the host device 200, and may control interoperability between the host device 200 and the memory system 100. The operating system may be classified into a general operating system and a mobile operating system depending on the mobility of the host device 200.

The host device 200 and the controller 120 may be separate devices. In some cases, the controller 120 may be implemented as a single device integrated with the host device 200. In this case, the function of the controller 120 may be implemented by being included in the host device 200, and the memory system 100 may include only a memory controller 112 that directly controls the operation of the memory 111. In the following, for the convenience of explanation, examples assume that the controller 120 and the host device 200 are separated from each other and the controller 120 is located in the memory system 100, but embodiments of the present disclosure are not limited thereto.

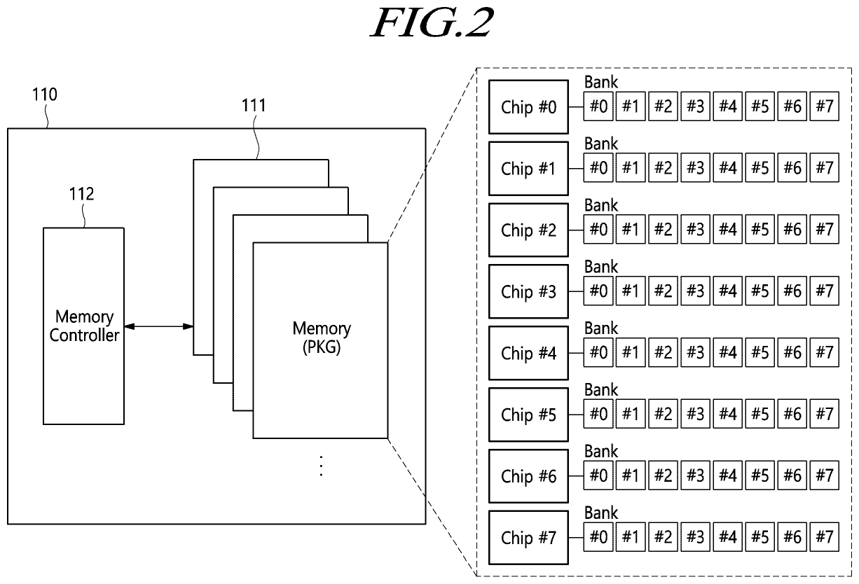

FIG. 2 illustrates a configuration of a memory device according to embodiments of the present disclosure.

Referring to FIG. 2, a memory device 110 may include a plurality of memories 111. The memory device 110 may include at least one memory controller 112 for controlling the plurality of memories 111.

In FIG. 2, a memory may mean a memory 111 including a single chip, or may mean a memory 111 in the form of a memory package in which a plurality of chips are packaged. FIG. 2 illustrates a memory 111 as a memory package composed of a plurality of chips.

Each of the plurality of memories 111 may include a plurality of chips. For example, one memory 111 may include eight chips #0, . . . , #7. Each of the eight chips #0, . . . , #7 may include a plurality of banks. A bank may mean a logical unit area within a chip where a write operation or a read operation is performed, and each chip may include, for example, eight banks #0, . . . , #7, but embodiments are not limited thereto in the number of memories, chips or banks.

Each bank may include a plurality of memory cells, and may be configured with a unit storage area including two or more memory cells. In this specification, a unit storage area may mean a storage area of various sizes that may be composed of memory cells, such as a memory cell, a plurality of memory cells, or a bank, included in a memory 111 or a chip.

Among the unit storage areas of each memory 111 included in the memory device 110, two or more unit storage areas may form a group and be used for data storage.

As an example, among the eight banks #0, . . . , #7 included in eight chips #0, . . . , #7, each bank #0 included in every chip may be gathered to form one group storage area. The memory controller 112 may configure one group storage area by combining each bank included in each chip, and may control an operation of writing data to the corresponding group storage area or reading data written to the corresponding group storage area. Within a chip, a use area is composed of unit storage areas that store data.

Since the memory controller 112 controls write and read operations of data by using a group storage area, which is spread over a plurality of banks included in different chips, it is possible to efficiently process a large amount of data in a short period of time.

The unit storage area may be composed of or may include two or more banks included in each chip, or the unit storage area may be a storage area that is smaller than a bank in each chip. Since the memory 111 processes data by operating using a group storage area composed of unit storage areas included in a plurality of chips, an operation of the memory 111 may be more efficiently performed.

A type of data stored in the unit storage area constituting the group storage area may be fixed, or different types of data may be stored in the unit storage area. For example, user data may be stored in all unit storage areas included in the group storage area. Alternatively, user data may be stored in some of the unit storage areas included in the group storage area, and parity data, which may be used to correct errors in the user data, may be stored in another part of the unit storage area included in the group storage area.

The user data and the parity data may be stored in each group storage area included in the memory 111 in a specific ratio. Data corresponding to the read command may be provided depending on an operation of reading the user data and parity data stored in the group storage area.

The function of encoding or decoding the user data and parity data may be performed by the memory controller 112. Alternatively, encoding or decoding may be performed by a component located outside the memory controller 112.

In addition, in some cases, the combination of user data and parity data stored in the group storage area may vary, and a plurality of configurations for processing various data combinations may be provided in the memory system 100.

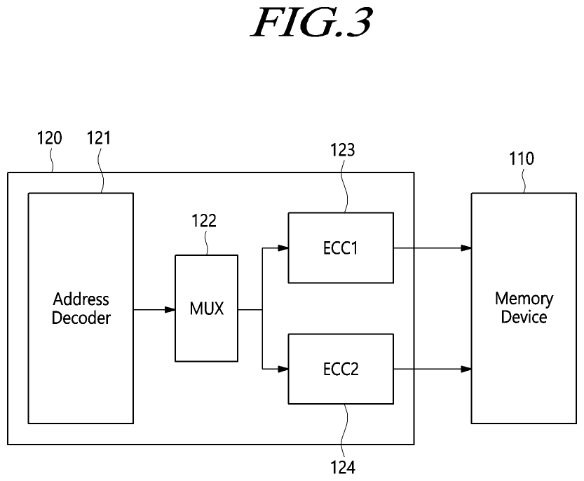

FIG. 3 illustrates a configuration of a controller according to embodiments of the present disclosure.

Referring to FIG. 3, a controller 120 may include, for example, an address decoder 121, a multiplexer 122, a first error correction circuit 123, and a second error correction circuit 124. Although FIG. 3 illustrates only a first error correction circuit 123 and a second error correction circuit 124, in other embodiments the controller 120 may include two or more error correction circuits.

The controller 120 may configure two or more unit storage areas of a memory 111 included in a memory device 110 as a group storage area, and may control a data processing operation for the group storage area. The data processing operation may mean an operation of performing processing on data to be written to the group storage area or performing processing on data read from the group storage area.

The controller 120 may exclude a unit storage area from the use area if a defect or a failure is detected in the unit storage area included in the memory 111 during operation of the memory 111.

The controller 120 may configure a group storage area using the remaining unit storage areas, while excluding a unit storage area which is determined to be defective.

If a unit storage area is excluded from the use area due to a defect, then the address decoder 121 of the controller 120 may exclude the address of the corresponding defective unit storage area from the addresses of unit storage areas corresponding to the use area. A unit storage area that is not included in, or excluded from, the use area may be referred to as an unuse area.

For example, the address decoder 121 may manage mapping relationships between host addresses (e.g., logical addresses) received from a host device 200 and memory addresses (e.g., physical addresses) of storage areas of the memory device 110.

If a unit storage area is identified as defective among the unit storage areas included in the memory device 110 and excluded from the use area, then the address decoder 121 may update the mapping relationship between the memory address and the host address of the defective unit storage area. The address decoder 121 may manage and distinguish an address corresponding to the use area from a defective address corresponding to a unit storage area excluded from the use area.

Memory addresses corresponding to unit storage areas included in the memory device 110 may be divided into addresses for use areas and addresses for unuse areas. An unuse area in a memory 111 included in the memory device 110 may be arranged in various ways. The configuration of group storage areas based on unit storage areas may be inconsistent due to the occurrence of unuse areas.

Using the address decoder 121, the controller 120 may check if a group storage area with unit storage areas requires data processing, and may control the method of processing the data stored in the unit storage areas depending on the configuration of the group storage area.

As an example, the controller 120 may process a command regarding data processing for a group storage area composed of unit storage areas, included in each memory 111 of the memory device 110, through the first error correction circuit 123. If a unit storage area is excluded from a group storage area and set as an unuse area, however, then the controller 120 may process a command regarding data processing for the group storage area, which is composed of remaining unit storage areas except for unit storage areas that are set as unuse areas, through the second error correction circuit 124.

The ratio of user data to parity data processed by the first error correction circuit 123 may be different from the ratio of user data to parity data processed by the second error correction circuit 124. The number or structure of unit storage areas included in the group storage area may be different due to the exclusion of some unit storage areas set to unuse areas among the memories 111 of the memory device 110. As a result, data processing by the first error correction circuit 123 or the second error correction circuit 124 may be performed differently according to different configurations of group storage areas.

As an example, data written to the memory device 110 may be encoded by the first error correction circuit 123 or encoded by the second error correction circuit 124.

The controller 120 may transmit a command and data to the first error correction circuit 123 or the second error correction circuit 124 through the multiplexer 122.

In some embodiments, when the controller 120 processes a read command, the read command may be transmitted to the memory device 110 and a read operation may be performed by a memory controller 112 (not illustrated) of the memory device 110. Data read from the memory device 110 may be transmitted to the first error correction circuit 123 or the second error correction circuit 124. Thus, depending on the group storage area from which the data is read, the read data may be transmitted to different error correction circuits, decoded, and then provided to the outside.

When a controller 120 controls a memory device 110 that includes a plurality of memories 111 and processes data according to a group storage area composed of a plurality of unit storage areas, the group storage area may be configured based on the remaining storage areas, excluding some defective areas within the memory device 110, so that it is possible to increase the utilization of the storage capacity of the memory device 110.

The controller 120 may, if necessary, control the setting of an unuse area in the memory device 110. When setting an unuse area, the controller 120 may update the address of the unuse area and reset the configuration of a group storage area.

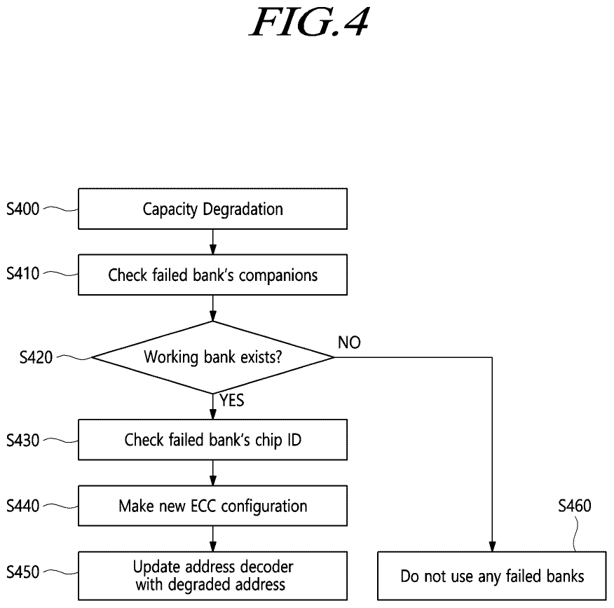

FIG. 4 illustrates a method for reducing available capacity of a memory system according to embodiments of the present disclosure.

Referring to FIG. 4, a controller 120 of a memory system 100 may check whether a capacity reduction or a capacity degradation is required in storage areas of a memory 111 included in a memory device 110. The controller 120 may perform capacity degradation if capacity degradation is required (S400).

As an example, the controller 120 may check whether a capacity reduction or capacity degradation is required through a test at booting time of the memory system 100, that is, checking whether there is a unit storage area to be excluded from the use area due to a defect. Alternatively, the controller 120 may set an unuse area based on a usage history of a unit storage area included in the memory 111.

When setting an unuse area, the controller 120 may also check whether there are other unit storage areas without defects, from among the unit storage areas associated with the unit storage area that is set as an unuse area. (S410). For example, referring to FIG. 2, if the unit storage area is a bank, and the group storage area is configured by the banks included in each memory 111, then controller 120 may check a failed bank's companions, i.e., other banks included in a chip.

From among the banks configuring the group storage area, the controller 120 may check whether there is an available unit storage area other than the banks which are detected as defective, which are set as unuse areas (S420). The controller 120 may check whether a working bank exists or not.

If there is an available (i.e., operable) bank within the group storage area, the controller 120 can check an ID (e.g., bank ID) of the failed unit storage area that is set as an unuse area (S430). The controller 120 may set a new group storage area using the existing unit storage areas except for the failed unit storage areas to be set as unuse areas (S440). The controller 120 may make a new ECC configuration based on the new group storage area. The controller 120 may set the address of the unuse area in the address decoder 121 as a degraded address and set the addresses of the new group storage area (S450). The controller 120 may update address decoder 121 accordingly.

If there is no available unit storage area (i.e., no operable bank) among the unit storage areas associated with the failed bank, then the controller 120 may set all of the unit storage areas to unused areas and may update the address decoder according to the setting information (S460). The controller 120 may not use any failed banks.

As described above, the controller 120 checks to determine whether a unit storage area of the memory 111 included in the memory device 110 has failed and must be set an unuse area. Thus, unit storage areas may be utilized as unit storage areas before an unuse area is set and before group storage areas are re-configured. The controller 120 can set the configuration of the group storage areas in different ways when unuse areas occur and can perform data processing using different error correction circuits, so the storage capacity of the memory 111 can be efficiently utilized even when an unuse area occurs.

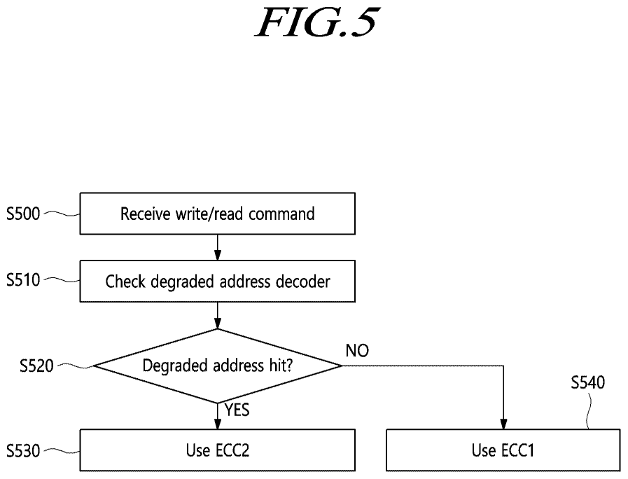

FIG. 5 illustrates a method of processing a command of a memory system when available data storage capacity is reduced according to embodiments of the present disclosure.

Referring to FIG. 5, a controller 120 may receive a write command or a read command from a host device 200 (S500).

If the controller 120 receives a command, the controller 120 may check an address according to the command using an address decoder 121 (S510).

The controller 120 may check whether the address according to the command is a degraded address of a unit storage area that has been set as an unuse area due to a defect (e.g., a failed bank in a chip). The controller 120 may also check whether the address according to the command is an address of a unit storage area associated with the defective unit storage area (e.g., check failed bank's companions). The controller 120 may check whether a degraded address is hit or not (S520).

If the address according to the command is a degraded address of an unuse area, or if an address according to the command is associated with a different unuse area, then the controller 120 may perform encoding or decoding of data according to the command by using the second error correction circuit 124 (S530). The controller 120 may perform encoding or decoding of data according to the command using the first error correction circuit 123 if the address according to the command does not correspond to a degraded address of an unuse area or an address associated with a different unuse area (S540).

Since the controller 120 sets an unuse area and configures a new group storage area using the remaining unit storage areas, it is possible to maximize the capacity of the memory 111 while preventing performance degradation of the memory system 100 due to occurrence of a defective area. The new group storage area may be configured in various ways, and the ratio or type of user data stored may be different depending on the configuration of the group storage area.

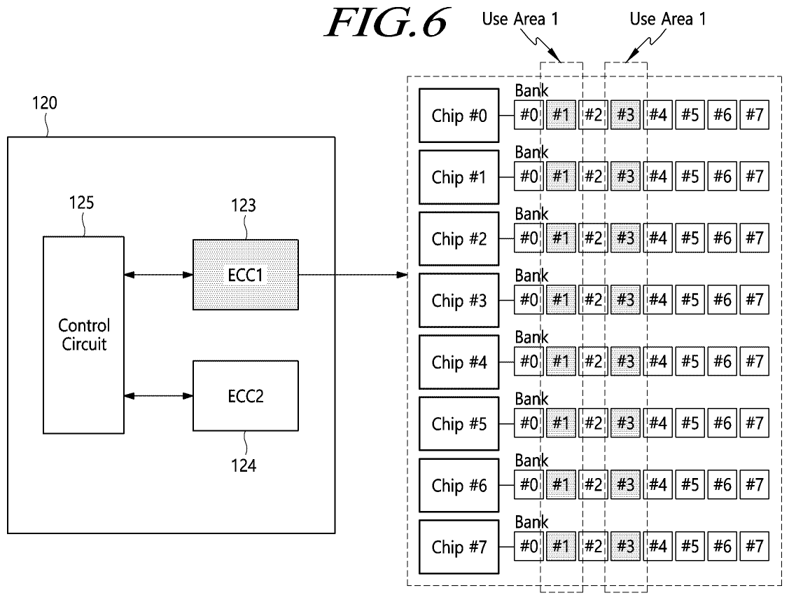

FIGS. 6 to 9 illustrate examples of methods of operating a memory system depending on whether available capacity is reduced according to embodiments of the present disclosure.

Referring to FIG. 6, a controller 120 may include a first error correction circuit 123 and a second error correction circuit 124. The controller 120 may include a control circuit 125. The control circuit 125 may be a circuit including at least a part of an address decoder 121 and an multiplexer 122 described above with reference to FIG. 3. The control circuit 125 may be a circuit for controlling the overall operation of the controller 120.

FIG. 6 illustrates a memory 111 included in a memory device 110 composed of eight chips #0, . . . , #7. Each of the eight chips #0, . . . , #7 may include eight banks #0, . . . , #7. Each of the eight banks #0, . . . , #7 may be a unit storage area. Each of the eight banks #0, . . . , #7 included in each of the eight chips #0, . . . , #7 can be combined with other banks to form a group storage area.

For example, a bank #0 included in each chip may be combined to form one group storage area. Similarly, a bank #1 included in each chip may be combined to form one group storage area, and a bank #3 included in each chip can be combined to form one group storage area.

Referring to FIG. 6, a group storage area is formed by banks #1 and #3 included in each chip of memory 111. In FIG. 6, the memory device 110 is in a state in which no unit storage areas are set as unuse areas, i.e., there are no defective unit storage areas included in the memory 111.

In FIG. 6, a first use area is a unit storage area, within a group storage area, that has not been set as unuse area. Bank #1 of each chip may be a first use area, and bank #1 of each chip may be combined or gathered to constitute or form a first group storage area. Bank #3 included in each chip may be a first use area, and bank #3 of each chip may be gathered or combined with banks #1 to constitute or form a first group storage area (Use Area 1). Banks in the first group storage area are also banks set as use areas.

The controller 120 may perform data processing for the first group storage area included in the memory 111.

For example, when the controller 120 receives a write command from a host device 200, the controller 120 may encode user data according to the write command using the first error correction circuit 123. The data encoded by the first error correction circuit 123 may include user data and parity data. A ratio of the user data and the parity data may be determined based on a ratio preset by the first error correction circuit 123, and may vary from 3:1 to 8:2, depending on the number or amount of data to be stored.

The data encoded by the first error correction circuit 123 may be written to a first group storage area (Use Area 1).

When the controller 120 receives a read command from the host device 200, the controller 120 may transmit the read command to the memory device 110 to perform a read operation. The controller 120 may receive data read by the memory device 110.

If it is confirmed that the address according to the read command corresponds to the first group storage area, then the controller 120 may process the read data through the first error correction circuit 123. The controller 120 may provide the data decoded by the first error correction circuit 123 to the host device 200.

The controller 120 may perform data processing for the first group storage area, which include banks configured as first use areas, by using the first error correction circuit 123 before a defective area occurs among the unit storage areas included in the first group storage area. Even after a defective area occurs among the unit storage areas included in the first group storage area, the controller 120 may perform data processing for the first group storage area, which includes banks configured as first use areas, by using the first error correction circuit 123.

When the controller 120 sets an unuse area after a defective area is detected among the unit storage areas of a first group storage area, the controller 120 may reconfigure the group storage area taking the unuse area into account and perform data processing on the reconfigured group storage area.

The controller 120 may detect a defective unit storage area from among the unit storage areas included in the memory 111, and may set the corresponding unit storage area as an unuse area.

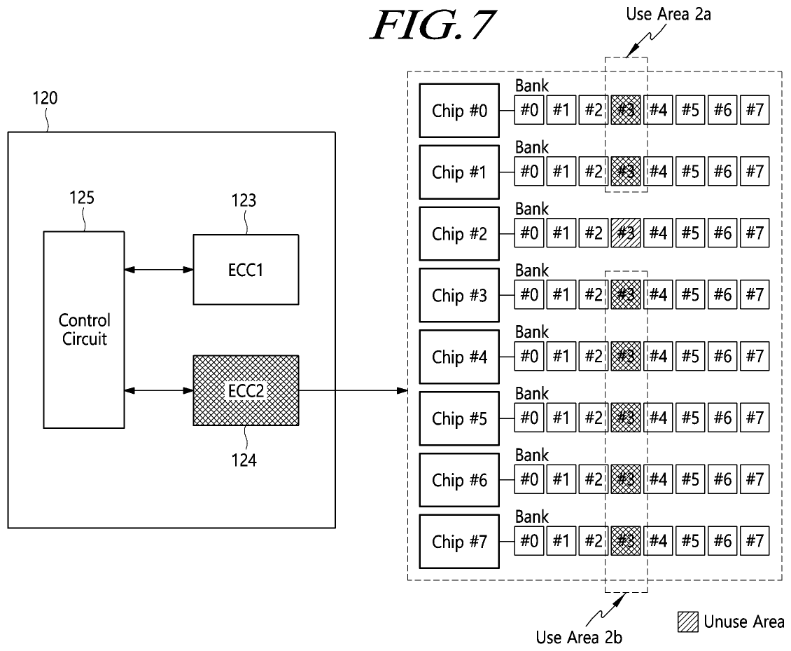

Referring to FIG. 7, the controller 120 may detect a bank #3 included in chip #2 included in a memory 111 as a defective area. The controller 120 may set the bank #3 included in chip #2 as an unuse area. The mapping relationship between a memory address and a host address included in the address decoder 121 may be updated according to the unuse area setting of the controller 120. The memory address corresponding to the bank #3 included in chip #2 may be classified and managed as a defective area with a degraded address.

If the bank #3 included in the chip #2 is set as an unuse area, then the controller 120 may reconfigure or reconstitute a group storage area by using the remaining unit storage areas of the original group storage area, but excluding the defective unit storage area.

For example, before the bank #3 of the chip #2 is set as an unuse area, bank #3 may be configured as a part of a first group storage area together with the bank #3 included in the chips #0, #1, #3˜#7.

After the bank #3 of the chip #2 is set as an unuse area, the bank #3 included in the remaining chips #0, #1, #3˜#7 may be configured as a new group storage area. The banks #3 included in the remaining chips #0, #1, #3˜#7 may be referred to as a second use area, and a group storage area configured by the banks #3 included in the remaining chips #0, #1, #3˜#7 may be referred to as a second group storage area. The number of unit storage areas constituting the first group storage area may be 8, and the number of unit storage areas constituting the second group storage area may be 7. The number of unit storage areas constituting each group storage area may be different from each other.

When receiving a command, the controller 120 may perform data processing for an area set as the second group storage area differently from data processing for the first group storage area.

For example, the controller 120 may process data according to a write command using a second error correction circuit 124 when receiving a write command for a second group storage area. The second error correction circuit 124 may encode user data and parity data according to the write command and provide the encoded data to the memory 111. A ratio of the user data and the parity data according to the second error correction circuit 124 may be different from a ratio of the user data and the parity data according to the first error correction circuit 123.

When the first group storage area is composed of eight banks and the second group storage area is composed of seven banks, if the ratio of user data and parity data according to the first error correction circuit 123 is 6:2, then the ratio of user data and parity data according to the second error correction circuit 124, such as 6:1 or 5:2, may be different from the ratio according to the first error correction circuit 123. The ratio of user data and parity data may be set differently for the first group storage area and the second group storage area, which is reconfigured due to the occurrence of an unuse area. In addition, the ratio of parity data in the second group storage area may be greater than that of the first group storage area. The remaining unit storage areas for the second group storage area, which is reconfigured due to an unuse area to exclude the unuse area, may be used without deterioration of data storage performance.

In addition, in some cases, the controller 120 may manage a type of data stored in the second group storage area differently from a type of data stored in the first group storage area. For example, the controller 120 may store user data in the first group storage area, and may store data including information for the controller 120 or an error correction circuit in the second group storage area. Without setting a separate parity ratio for the second group storage area, which has a different configuration of the unit storage area due to the unuse area, the second group storage area may be utilized as an area for storing other types of data.

The controller 120 may configure a group storage area excluding a defective unit storage area as a new group storage area on occurrence of an unuse area, and may store user data or other types of data using the new group storage area. Thus, even if an unuse area occurs, other unit storage areas associated with the unuse area may be configured and utilized in a new group storage area. As a result, there may be prevented an inefficient degradation of the available unit storage areas of the memory 111 due to the occurrences of unuse areas, and there the efficiency of the storage capacity of the memory 111 may increase.

The second group storage area, newly configured after the occurrence of the unuse area, may be set in various ways, and in some cases, the second group storage area may be set to a structure including a larger number of banks than the number of banks in the first group storage area.

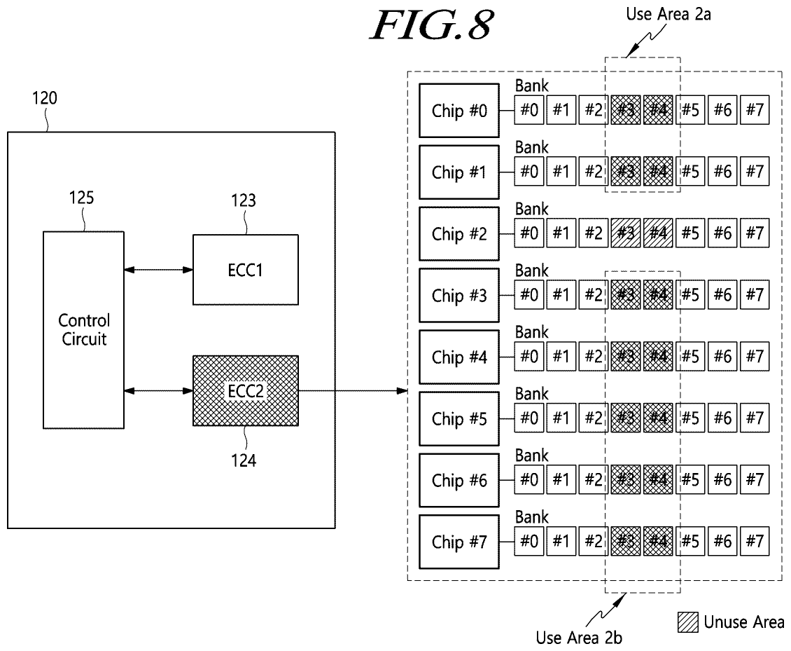

As an example, referring to FIG. 8, banks #3 and #4 included in chip #2 of a memory 111 may be detected as defective areas by the controller 120. The banks #3 and #4 of chip #2 may be set as unuse areas.

Before bank #3 of chip #2 is set as an unuse area, bank #3 of chip #2 may be configured as part of a first group storage area together with the banks #3 included in the remaining chips #0, #1, #3˜#7. Before bank #4 of chip #2 is set as an unuse area, the bank #4 of chip #2 may be configured as part of a first group storage area with banks #4 included in the remaining chips #0, #1, #3˜#7.

After the banks #3 and #4 of chip #2 are set as unuse areas, the banks #3 and #4 included in the remaining chips #0, #1, #3˜#7 excluding chip #2 may be set as second use areas. The controller 120 may configure or form a second group storage area using banks #3 and #4 included in the remaining chips #0, #1, #3˜#7, which correspond to the second use areas. The controller 120 may configure the second group storage area in various ways.

For example, the controller 120 may configure a second group storage area using banks #3 included in the remaining chips #0, #1, #3˜#7. The controller 120 may configure a second group storage area using banks #4 included in the remaining chips #0, #1, #3˜#7.

The number of banks configuring the second group storage area may be smaller than the number of banks configuring the first group storage area. The ratio of user data to parity data stored in the second group storage area may be different from the ratio of user data to parity data stored in the first group storage area. In other embodiments, the second group storage area may store data of different types from data stored in the first group storage area.

As another example, the controller 120 may configure one second group storage area by using all of banks #3 and #4 included in the remaining chips #0, #1, #3 to #7 (in FIG. 8, Use Areas 2a and 2b).

In some embodiments illustrated in FIG. 8, the number of banks constituting the second group storage area may be greater than the number of banks constituting the first group storage area. For example, the number of banks constituting the second group storage area may be 14, and the number of banks constituting the first group storage area may be 8. The ratio of user data to parity data stored in the second group storage area may be different from the ratio of user data to parity data stored in the first group storage area. As the number of banks included in the second group storage area increases, the decrease in the ratio of parity data may be minimized, thereby increasing the reliability of data stored in the second group storage area. In addition, data of a different type from that stored in the first group storage area may be stored in the second group storage area.

Accordingly, the second group storage area may be configured and utilized in various ways according to the occurrence of unuse areas, so that it is possible to minimize the decrease in available unit storage areas due to the increase in unuse areas, and any decrease in reliability of the second use area may be reduced.

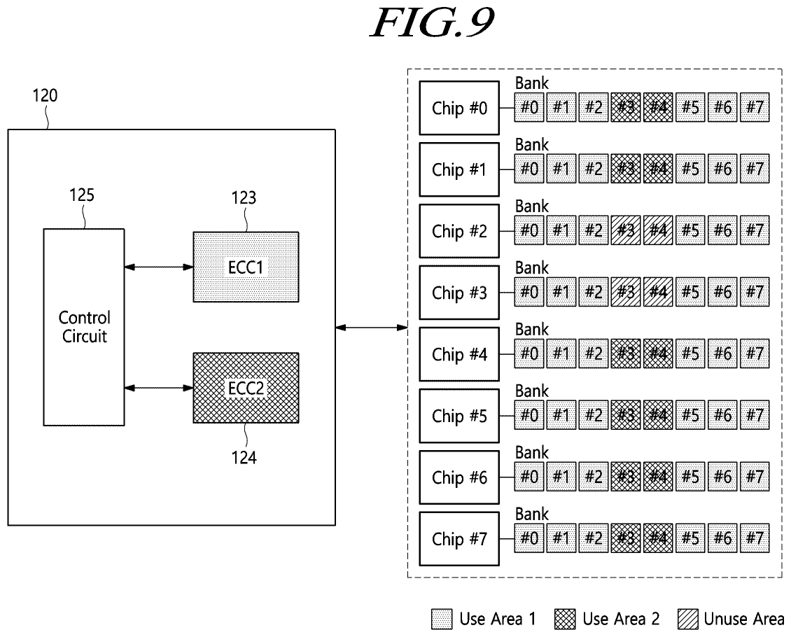

The first use area, the second use area, and the unuse area may be set in various ways. For example, as in the example illustrated in FIG. 9, among chips #0 to #7 of a memory 111, banks #3 and #4 included in chip #2 and banks #3 and #4 included in chip #3 may be set as unuse areas. Banks #3 and #4 included in chips #0, #1, #4 to #7, excluding chips #2 and #3, may be second use areas (Use Area 2). The remaining banks excluding the unuse area and the second use areas may be first use areas (Use Area 1).

The controller 120 may configure a first group storage area using the first use area, and perform data processing for the first group storage area using the first error correction circuit 123. The controller 120 may configure a second group storage area using the second use area, and perform data processing for the second group storage area using the second error correction circuit 124.

The second group storage area may be configured only with the remaining unit storage areas excluding the unuse areas in the existing first group storage area, as in the example described above, or may be configured by arranging the remaining unit storage areas, excluding the unuse area, in two or more first group storage areas.

According to embodiments of the present disclosure, it is possible to increase the utilization efficiency of a unit storage area excluding a defective area in a memory 111, and the embodiments of the present disclosure may be applied to various types of memory systems 100.

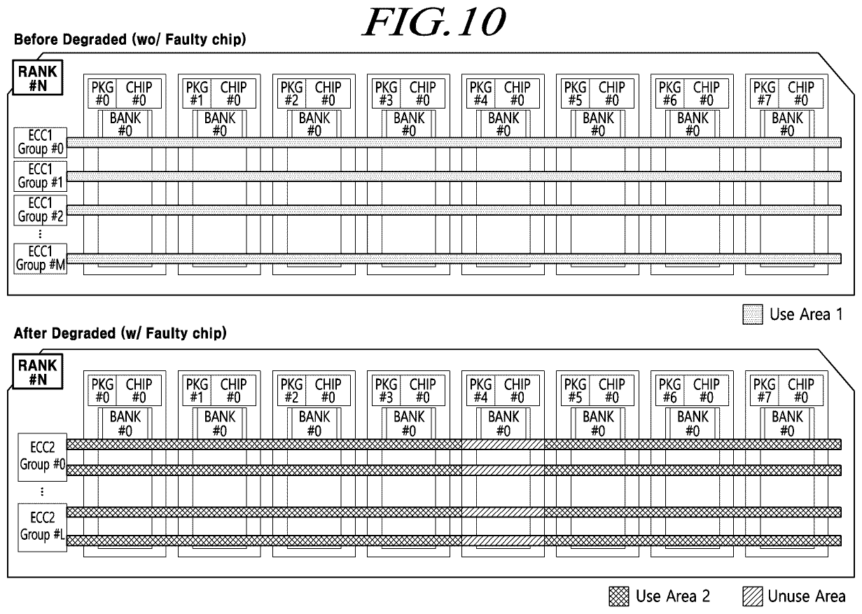

FIG. 10 illustrates a method of operating a memory module depending on whether a faulty chip is included according to embodiments of the present disclosure.

Referring to FIG. 10, a memory module may include a plurality of memory packages. Each of the plurality of memory packages may include at least one chip, and each chip may include a plurality of banks. FIG. 10 illustrates an example in which a memory module includes eight memory packages. In addition, although not shown, a memory module may include a memory controller 112 for controlling the operation of the memory packages.

Before a faulty chip or a defective chip occurs among the chips included in the memory module, a unit storage area included in each chip may correspond to a first use area. If the unit storage area corresponds to a bank, the banks included in each memory package may be selected and combined to constitute or form a first group storage area.

Data processing by an error correction circuit may be performed for each first group storage area. Each first group storage areas formed by the banks of each memory package may form an error correction circuit (ECC) group #0, . . . , #M.

If a faulty chip occurs among the chips included in the memory module, at least a portion of the unit storage area included in the faulty chip may be set as an unuse area.

For example, if a bank included in the memory package #4 is set as an unuse area, then the bank set as the unuse area is excluded and the remaining banks of the first group storage area may form or constitute a second group storage area configured as a second use area. For example, the banks included in the memory packages #0 to #3 and #5 to #7 may form the second group storage area, and in some cases, an error correction circuit group #0, . . . , #L may be formed as a unit of two banks included in each memory package.

The second group storage area may be configured by a different combination of banks than the group of banks before a faulty chip occurred, and data processing may be performed on the reconfigured second group storage area.

Accordingly, even if a defective unit storage area occurs, it is possible to minimize the decrease or degradation in storage capacity of the memory module and improve the usage efficiency of the memory module by using a second group storage area based on the combination of the remaining unit storage areas.

Based on embodiments of the disclosed technology described above, the operation delay time of the memory system may be advantageously reduced or minimized. In addition, based on an embodiment of the disclosed technology, an overhead occurring in the process of calling a specific function may be advantageously reduced or minimized. Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A memory system comprising:
an N (where N is an integer greater than or equal to 2) number of memory devices each including a plurality of unit storage areas; and
a controller configured to set at least one use area and at least one unuse area from among the plurality of unit storage areas in the N memory devices, to control a first data processing for a first group storage area including a first use area included in each of the N memory devices, and to control a second data processing for a second group storage area, which excludes at least one of the N memory devices including an unuse area after the unuse area is determined, wherein the second group storage area includes a second use area included in each of the remaining memory devices from among the N memory devices.

2. The memory system of claim 1, wherein the first group storage area includes N first use areas, and the second group storage area includes an M (where M is an integer greater than or equal to 2) number of second use areas,
wherein M is different from N.

3. The memory system of claim 1, wherein a ratio of user data to parity data stored in the first group storage area is different from a ratio of user data to parity data stored in the second group storage area.

4. The memory system of claim 1, wherein a type of data stored in the first group storage area is different from a type of data stored in the second group storage area.

5. The memory system of claim 1, wherein the first group storage area includes one first use area included in each of the N memory devices, and the second group storage area includes two or more second use areas included in each of the remaining memory devices.

6. The memory system of claim 1, wherein the controller comprises:
a first error correction circuit for encoding or decoding data for the first group storage area according to the first data processing; and
a second error correction circuit for encoding or decoding data for the second group storage area according to the second data processing.

7. The memory system of claim 6, wherein the controller comprises:
an address decoder for checking a memory address corresponding to a host address according to a command received from a host device; and
a multiplexer for transmitting user data according to the command to the first error correction circuit or the second error correction circuit based on the memory address.

8. The memory system of claim 7, wherein the controller updates the memory address managed by the address decoder when setting the unuse area.

9. The memory system of claim 1, wherein the controller tests some of the plurality of unit storage areas at boot time, and sets the at least one use area and the at least one unuse area.

10. The memory system of claim 1, wherein the second use area and the second group storage area include the unuse area before the unuse area is determined.

11. The memory system of claim 1, wherein at least one of the N memory devices includes a first use area and an unuse area.

12. The memory system of claim 1, wherein at least one of the N memory devices includes a first use area and a second use area.

13. A controller comprising:
an address decoder for checking a memory address corresponding to a host address according to a command received from a host device; and
a control circuit configured to set a plurality of unit storage areas included in an N (where N is an integer greater than or equal to 2) number of memory devices as a use area or an unuse area, and to control a first data processing for a first group storage area including a first use area included in each of the N memory devices or a second data processing for a second group storage area including a second use area included in each of the memory devices remaining after excluding at least one memory device with an unuse area from among the N memory devices.

14. The controller of claim 13, further comprising:
a first error correction circuit for encoding or decoding data for the first group storage area according to the first data processing; and
a second error correction circuit for encoding or decoding data for the second group storage area according to the second data processing.

15. The controller of claim 14, further comprising a multiplexer for transmitting user data according to the command to the first error correction circuit or the second error correction circuit based on the memory address checked by the address decoder.

16. The controller of claim 14, wherein a ratio of user data to parity data included in the data converted by the first error correction circuit is different from a ratio of user data to parity data included in the data converted by the second error correction circuit.

17. A memory module comprising:
a first memory including a plurality of first unit storage areas with at least one first use area and at least one second use area;
a second memory including a plurality of second unit storage areas with at least one first use area and at least one second use area;
a third memory including a plurality of third unit storage areas with at least one first use area and at least one unuse area; and
a memory controller configured to control an operation for a first group storage area including the first use area of the first memory, the first use area of the second memory, and the first use area of the third memory, or control an operation for a second group storage area including the second use area of the first memory and the second use area of the second memory.

18. The memory module of claim 17, wherein a ratio of user data to parity data stored in the first group storage area is different from a ratio of user data to parity data stored in the second group storage area.

19. The memory module of claim 17, wherein the memory controller receives data to be written in the first group storage area from a first error correction circuit, and receives data to be written in the second group storage area from a second error correction circuit different from the first error correction circuit.

20. The memory module of claim 17, wherein the memory controller transfers data read from the first group storage area to a first error correction circuit, and transfers data read from the second group storage area to a second error correction circuit different from the first error correction circuit.
